(19) United States
(12) Patent Application Publication
(10) Pub. No.: US 2026/0239724 A1
(43) Pub. Date: Aug. 13, 2026

(54) SEMICONDUCTOR DEVICE AND MANUFACTURING METHOD

(71) Applicants: Kabushiki Kaisha Toshiba, Kawasaki-shi (JP); Toshiba Electronic Devices & Storage Corporation, Kawasaki-shi (JP)

(72) Inventors: Shinnosuke KASHIWA, Nonoichi Ishikawa (JP); Hidenobu KOJIMA, Kanazawa Ishikawa (JP); Shunta MURAI, Kanazawa Ishikawa (JP)

(21) Appl. No.: 19/309,551

(22) Filed: Aug. 25, 2025

(30) Foreign Application Priority Data
Feb. 7, 2025 (JP) 2025-018837

(51) Int. Cl. H10D 84/00; H10D 8/00; H10D 8/01; H10D 12/00; H10D 12/01; H10D 62/10; H10D 62/53

(52) U.S. Cl. CPC H10D 84/161; H10D 8/045; H10D 8/422; H10D 12/038; H10D 12/481; H10D 62/103; H10D 62/124; H10D 62/53

(57) ABSTRACT

According to one embodiment, a semiconductor device includes a semiconductor substrate having a transistor region and a diode region spaced from the transistor region. A first electrode is on one side of the substrate, and a second electrode is on the other. The second electrode has a first surface in the transistor region and a second surface in the diode region that is closer to the substrate than is the first surface. Gate electrodes are in the semiconductor substrate. The semiconductor substrate includes a first semiconductor region on the first electrode, a second semiconductor region on the first semiconductor region and between adjacent pairs of gate electrodes, a third semiconductor region in the transistor region on the second semiconductor region, and a defect region. The defect region has a higher crystal defect density than a crystal defect density of the semiconductor substrate outside the defect region.

### CROSS-REFERENCE TO RELATED APPLICATION

This application is based upon and claims the benefit of priority from Japanese Patent Application No. 2025-018837, filed Feb. 7, 2025, the entire contents of which are incorporated herein by reference.

### FIELD

Embodiments described herein relate generally to a semiconductor device and a manufacturing method for a semiconductor device.

### BACKGROUND

A semiconductor element referred to as a reverse conductive (RC)-IGBT is known. Such an element includes an insulated gate bipolar transistor (IGBT) and a diode. Crystal defects may be introduced into a semiconductor substrate to control a carrier lifetime in such elements.

### BRIEF DESCRIPTION OF THE DRAWINGS

FIG. 1 is a schematic top view illustrating a semiconductor device according to a first embodiment.

FIG. 2 is a cross-sectional view of a semiconductor device according to a first embodiment.

FIG. 3 is a cross-sectional view of a semiconductor device according to a second embodiment.

FIG. 4 is a cross-sectional view of a semiconductor device according to a third embodiment.

FIG. 5 is a cross-sectional view of a semiconductor device according to a fourth embodiment.

FIG. 6 is a cross-sectional view of a semiconductor device according to a fifth embodiment.

FIG. 7 is a cross-sectional view of a semiconductor device according to a sixth embodiment.

FIG. 8 is a cross-sectional view of a semiconductor device according to a seventh embodiment.

FIGS. 9 to 13 depict aspects of a manufacturing method of a semiconductor device according to a first embodiment.

### DETAILED DESCRIPTION

Embodiments provide a semiconductor device capable of reducing losses during switching.

In general, according to one embodiment, a semiconductor device includes a semiconductor substrate having a transistor region and a diode region spaced from the transistor region, a first electrode on a first side of the semiconductor substrate, and a second electrode on a second side of the semiconductor substrate. The second electrode has a first upper surface in the transistor region and a second upper surface in the diode region. The second upper surface is closer to the semiconductor substrate than is the first upper surface. A plurality of gate electrode is in the semiconductor substrate between the first and second electrodes in a first direction. Each gate electrode is surrounded by a gate insulating film. The semiconductor substrate further includes: a first semiconductor region on the first electrode; a second semiconductor region on the first semiconductor region and between adjacent pairs of gate electrodes in the plurality of gate electrodes; a third semiconductor region in the transistor region on the second semiconductor region; and a defect region, the defect region having a higher crystal defect density than a crystal defect density of the semiconductor substrate outside the defect region.

According to another embodiment, a semiconductor device includes a semiconductor substrate having a transistor region and a diode region spaced from the transistor region, a first electrode on a first side of the semiconductor substrate, a second electrode on a second side of the semiconductor substrate, and a plurality of gate electrodes in the semiconductor substrate between the first and second electrodes in a first direction. Each gate electrode is surrounded by a gate insulating film. The semiconductor substrate also includes: a first semiconductor region on the first electrode; a second semiconductor region on the first semiconductor region and between adjacent pairs of gate electrodes in the plurality of gate electrodes; a third semiconductor region in the transistor region on the second semiconductor region; and a defect region. The defect region has a higher crystal defect density than a crystal defect density of the semiconductor substrate outside the defect region and is in the second semiconductor region in the transistor region and the first semiconductor region in the diode region.

According to one embodiment, a manufacturing method for a semiconductor device includes: preparing a semiconductor substrate having a transistor region and a diode region, the semiconductor substrate including a first semiconductor region of a first conductivity type, a second semiconductor region of a second conductivity type, the second semiconductor region being provided on the first semiconductor region, a third semiconductor region of the first conductivity type, the third semiconductor region being provided on the second semiconductor region in the transistor region, and a plurality of gate electrodes facing the second semiconductor region with a gate insulating portion interposed therebetween; forming an upper electrode on the semiconductor substrate; forming a resist on the upper electrode, the resist having an opening above the second semiconductor region in the diode region; selectively removing an upper portion of the upper electrode so as to form a first upper surface in the transistor region and a second upper surface in the diode region, the second upper surface being formed closer to the semiconductor substrate than the first upper surface; and implanting a dopant into the semiconductor substrate through the upper electrode so as to form a defect region in the semiconductor substrate, the defect region having a higher crystal defect density than a crystal defect density of the semiconductor substrate outside the defect region.

Hereinafter, certain example embodiments of the present disclosure will be described with reference to the drawings.

It is noted that the drawings are schematic or conceptual, and, as such, any depicted relationship between dimensions, such as the thickness and the width, of depicted components, the relative size ratios between the components, and the like are not necessarily the same as in actuality. Furthermore, even when the same components are represented in different drawings, the depicted dimensions and the ratios of the respective components may be different depending on the drawing.

For example, in the cross-sectional view illustrated in the present specification, a stacked structure is illustrated, but the relative thicknesses of each layer in the stacked structure is not necessarily the same as an actual one. Thus, even if one layer is shown to be thicker than another layer in the cross-sectional view, in reality, the thicknesses of the layers may be substantially the same or one layer may be thinner than the other layer. That is, the dimensions such as layer thickness as illustrated in the drawings of the present specification may be different from actuality.

A direction from a first electrode 11 to a second electrode 12 is defined as a Z direction. A direction orthogonal to the Z direction is defined as an X direction, and a direction intersecting the X and Z directions is defined as a Y direction. In the present embodiment, although the X direction, the Y direction, and the Z direction are shown to be orthogonal to each other, the respective directions may intersect each other without being limited to a strictly orthogonal relationship therebetween.

For the sake of description, a positive direction in the Z direction is referred to as “upward” and a negative direction in the Z direction is referred to as “downward”. However, the directions of “upward” and “downward” are not limited to the direction of gravity or the direction when a semiconductor device is mounted. When a vertical positional relationship between regions having different positions on an XY plane is described, the positions of the regions in the Z direction may be compared with each other.

In the following descriptions, notations n⁺, n, n⁻, p⁺, p, and p⁻ each represent a relatively high and low state of impurity concentration in each conductivity type. That is, n⁺ indicates that n-type impurity concentration is relatively higher than n, and n⁻ indicates that n-type impurity concentration is relatively lower than n. Further, p⁺ indicates that p-type impurity concentration is relatively higher than p, and p⁻ indicates that p-type impurity concentration is relatively lower than p. It is noted that, in some cases, n⁺ type and n⁻ type may be simply referred to as n-type, and p⁺ type and p⁻ type may be simply referred to as p-type.

It is noted that, in the present specification and each drawing, elements similar to those previously described with reference to other drawings will be denoted by the same reference symbols, and additional descriptions thereof may be omitted as appropriate.

### First Embodiment

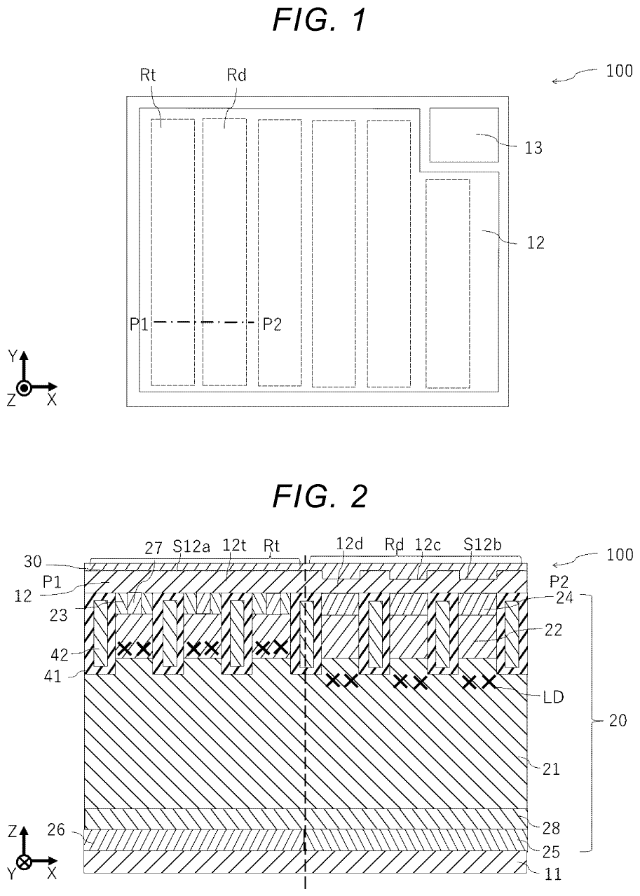

FIG. 1 is a schematic top view of a semiconductor device 100 according to a first embodiment. FIG. 2 is a cross-sectional view taken along line P1-P2 illustrated in FIG. 1.

The semiconductor device 100 illustrated in FIG. 1 is, for example, an RC-IGBT. Although not visible in the top view of FIG. 1, the semiconductor device 100 has a first electrode 11 (which functions as a collector electrode of an IGBT and a cathode electrode of a diode). A second electrode 12 functions as an emitter electrode of the IGBT and an anode electrode of the diode. A third electrode 13 is a gate pad connected to a gate electrode of the IGBT. The semiconductor device 100 has a transistor region Rt and a diode region Rd. The transistor region Rt and the diode region Rd are spaced from each other in the X direction and extend in the Y direction. It is noted that the total number of transistor regions Rt and diode regions Rd and the width thereof in the X direction can be optimized as appropriate for a particular semiconductor device 100. FIG. 1 is merely an example configuration.

It is noted that, although FIG. 1 is a diagram of a first embodiment, aspects of a cross-section taken at line P1-P2 illustrated in FIG. 1 will also be used for description of subsequent embodiments after the first embodiment is explained.

FIG. 2 is a view illustrating an XZ cross section taken along the line P1-P2 illustrated in FIG. 1. In FIG. 2, the IGBT is formed in the transistor region Rt, and a free-wheeling diode (FWD) is formed in the diode region Rd.

The semiconductor device 100 has the first electrode 11 (the collector electrode of the IGBT or the cathode electrode of the diode), a first semiconductor region 21 (a n⁻ type drift region) of a first conductivity type, which is provided on the first electrode 11, a second semiconductor region 22 (a p-type base region) of a second conductivity type, which is provided on the first semiconductor region 21 in the transistor region Rt and the diode region Rd, and a third semiconductor region 23 (a n⁺ type emitter region) of the first conductivity type, which is provided on the second semiconductor region 22 in the transistor region Rt. Further, the semiconductor device 100 has a fourth semiconductor region 24 (a p⁺ type anode region) of the second conductivity type, which is provided on the second semiconductor region 22 in the diode region Rd. In the following description, the second semiconductor region 22 in the transistor region Rt and the second semiconductor region 22 in the diode region Rd will be described using a common reference symbol, but it is not necessary that the second semiconductor region 22 in the transistor region Rt and the second semiconductor region 22 in the diode region Rd have the same impurity concentration.

In the diode region Rd, the semiconductor device 100 has a fifth semiconductor region 25 (a n⁺ type cathode region) of the first conductivity type, which is provided between the first electrode 11 and the first semiconductor region 21. When the IGBT is formed in the transistor region Rt, the semiconductor device 100 has a sixth semiconductor region 26 (a p⁺ type collector region) of the second conductivity type, which is provided between the first electrode 11 and the first semiconductor region 21 in the transistor region Rt.

In addition, in the transistor region Rt, the semiconductor device 100 may have a seventh semiconductor region 27 (a p⁺ type contact region) of the second conductivity type, which is provided on the second semiconductor region 22.

The semiconductor device 100 has a buffer region 28 (also referred to an eighth semiconductor region 28, a n⁺ type buffer region) on the fifth semiconductor region 25, and the sixth semiconductor region 26.

In the transistor region Rt, a gate insulating portion 41 extends from the second electrode 12 toward the first semiconductor region 21. A gate electrode 42 is provided in the gate insulating portion 41. The gate electrode 42 faces the second semiconductor region 22 with the gate insulating portion 41 interposed therebetween. The gate insulating portions 41 and the gate electrodes 42 are arranged in the X direction and extend in the Y direction. The gate insulating portions 41 and the gate electrodes 42 are also provided in the diode region Rd.

The structure of the second electrode 12 will be described. The second electrode 12 includes an emitter electrode 12t located in the transistor region Rt and an anode electrode 12d located in the diode region Rd. The emitter electrode 12t has a first upper surface S12a. The anode electrode 12d has a second upper surface S12b. At least a part of the upper surface of the anode electrode 12d may be the first upper surface S12a. The second electrode 12 may also be referred to as an upper electrode.

The first upper surface S12a has a flat surface shape. The second upper surface S12b is closer to the first electrode 11 than the first upper surface S12a. In other words, the second upper surface S12b includes a surface located further in the negative direction of the Z direction than the first upper surface S12a.

When the location of the first upper surface S12a in the Z direction is set as a reference level, a recess portion 12c (a groove portion) is formed in the anode electrode 12d. The second upper surface S12b is the bottom surface of the recess portion 12c.

A region in which the recess portion 12c is formed in the diode region Rd overlaps, in the Z direction, at least a part of the second semiconductor region 22 located between the gate insulating portions 41. For example, in the recess portion 12c (the second upper surface S12b), an area of a portion overlapping, in the Z direction, the second semiconductor region 22 located between the gate insulating portions 41 is less than an area of a portion overlapping the gate insulating portion 41 in the Z direction. Desirably, the recess portion 12c is provided at a location allowing the recess portion 12c to overlap the second semiconductor region 22 located between the gate insulating portions 41 in the Z direction, but not allowing the recess portion 12c to overlap the gate insulating portion 41 in the Z direction. In other words, it is desirable to selectively provide the recess portion 12c above just the second semiconductor region 22. The recess portion 12c is not located above the gate insulating portion 41, and the second electrode 12 is relatively thick. When shielding performance against impurity injection is improved and impurities are injected (implanted) through the second electrode 12, inclusion the impurities in the gate insulating portion 41 is prevented or reduced. As a result, deterioration in insulating performance of the gate insulating portion 41 is avoided.

A conductive layer 30 is formed on the second electrode 12. The conductive layer 30 is, for example, a plated layer. The conductive layer 30 contacts the second upper surface S12b of the second electrode 12. That is, the conductive layer 30 is formed by filling the recess portion 12c of the anode electrode 12d. The upper surface of the conductive layer 30 is desirably flat.

A defect region LD (a lifetime control region) is provided across the transistor region Rt and the diode region Rd. The defect region LD is a region having a crystal defect density of, for example, about 10⁴ times or more of a crystal defect density in the first semiconductor region 21 (a portion outside the defect region LD). The defect region LD can be formed, for example, by helium injection. The location of the defect region LD in the Z direction can be estimated, for example, by measuring a distribution of helium in the Z direction and detecting the location of a peak in helium concentration.

In the transistor region Rt, the defect region LD is provided in the second semiconductor region 22. In the transistor region Rt, the defect region LD is located between the first semiconductor region 21 and the second electrode 12 in the Z direction. In other words, a distance between the defect region LD and the second electrode 12 is shorter than a distance between the first semiconductor region 21 and the second electrode 12. In the transistor region Rt, the defect region LD is located in the second semiconductor region 22 and the third semiconductor region 23 (or the seventh semiconductor region 27). Desirably, the defect region LD is located further in the negative Z direction (located farther away from the second electrode 12) than the third semiconductor region 23 and is located in the second semiconductor region 22.

In the diode region Rd, the defect region LD is provided in the first semiconductor region 21. A maximum value of a profile in the Z direction of the defect density in the defect region LD is located in the first semiconductor region 21. The defect region LD in the diode region Rd is, for example, closer to the second semiconductor region 22 than to the fifth semiconductor region 25.

A crystal defect density in the portion of the first semiconductor region 21 that overlaps the second semiconductor region 22 located between the gate insulating portions 41 in the Z direction is higher than a crystal defect density in the portion of the first semiconductor region 21 that overlaps the gate insulating portions 41 in the Z direction. Desirably, the defect region LD located in the first semiconductor region 21 of the diode region Rd is selectively formed in the portion of the first semiconductor region 21 that overlaps, in the Z direction, with the second semiconductor region 22 located between the gate insulating portions 41.

Next, the structures of the first semiconductor region 21 and the second semiconductor region 22 will be further described. An interface between the first semiconductor region 21 and the second semiconductor region 22 is a planar across the transistor region Rt and the diode region Rd. Regarding the distance between the interface between the first semiconductor region 21 and the second semiconductor region 22 and the second electrode, the difference between the distance in the transistor region and the distance in the diode region is, for example, less than 10% of the larger distance of the distances in the transistor region Rt and the diode region Rd. That is, in the case of a planar interface, a variation of, for example, about 10% or less may be present. Although the second semiconductor region 22 is formed, for example, by injecting impurities of the second conductivity type into the semiconductor substrate 20 of the first conductivity type, the second semiconductor region 22 may be formed across the transistor region Rt and the diode region Rd in the same impurity injection step.

The interface between the first semiconductor region 21 and the second semiconductor region 22 in the diode region Rd is located closer to the first electrode 11 in the Z direction than the defect region LD in the transistor region Rt. The interface between the first semiconductor region 21 and the second semiconductor region 22 in the transistor region Rt is located farther away from the first electrode 11 in the Z direction than the defect region LD in the diode region Rd.

In FIG. 2, the recess portion 12c overlaps, in the Z direction, the defect region LD in the first semiconductor region 21 in the diode region Rd. The formation of the first upper surface S12a and the second upper surface S12b on the upper surface of the second electrode 12 corresponds to a location difference in the Z direction between the defect region LD in the transistor region Rt and the defect region LD in the diode region Rd.

Next, an example of each material will be described.

Each of the first electrode 11 and the second electrode 12 can be a metal comprising, for example, Al or Cu.

The semiconductor substrate 20 that has the first semiconductor region 21, the second semiconductor region 22, the third semiconductor region 23, the fourth semiconductor region 24, the fifth semiconductor region 25, the sixth semiconductor region 26, the seventh semiconductor region 27, and the buffer region 28, is a semiconductor material such as, for example, silicon (Si). The semiconductor region of the n-type conductivity type is formed, for example, by injecting phosphorus (P) and performing annealing processing. The semiconductor region of the p-type conductivity type is formed, for example, by injecting boron (B) and performing annealing processing. It is noted that the buffer region 28 can be formed, for example, by injecting protons (H⁺) or helium (He).

The conductive layer 30 is, for example, a plated metal comprising at least one of nickel (Ni), palladium (Pd), and gold (Au). The conductive layer 30 comprises, for example, two layers such as one layer containing Ni, which is provided on the second electrode 12, and another layer containing Au on the layer containing Ni.

The gate insulating portion 41 is, for example, an oxide film such as silicon oxide. The gate electrode 42 is, for example, conductive polysilicon (doped polysilicon).

Next, a description will be given as to the operation of the semiconductor device 100. A description will be given as to an operation in which the IGBT in the transistor region Rt is turned on, and after the IGBT in the transistor region Rt is turned off, the diode in the diode region Rd is electrically connected.

First, the operation of the transistor region Rt will be described. When a voltage equal to or greater than a threshold voltage is applied to the gate electrode 42 while a positive voltage is applied to the first electrode 11 with respect to the second electrode 12, an inversion layer (a channel) of the first conductivity type is generated in the second semiconductor region 22. Injection of electrons starts from the second electrode 12, and the electrons sequentially pass through the third semiconductor region 23 and the inversion layer of the second semiconductor region 22 so as to be injected into the first semiconductor region 21. Then, the injection of holes starts from the first electrode 11, and the holes pass through the fifth semiconductor region 25 so as to be injected into the first semiconductor region 21. The IGBT is “turned on” (made conductive) using injected electrons and holes each serving as a carrier.

Subsequently, when the voltage applied to the gate electrode 42 is made to be less than the threshold voltage, the inversion layer of the first conductivity type formed in the second semiconductor region 22 disappears, the injection of electrons stops, and a turn-off operation of the IGBT starts. When the IGBT is in the on state, the electrons stored in the first semiconductor region 21 are discharged to the second electrode 12, and the holes are discharged to the first electrode 11.

Next, a freewheeling operation of the diode will be described. In some cases, in the operation of the RC-IGBT, current flows from the second electrode 12 to the first electrode 11. At this time, the diode in the diode region Rd permits current to flow from the second electrode 12 (anode electrode) to the first electrode 11 (cathode electrode). During the freewheeling operation, the injection of holes starts from the second electrode 12, and the holes pass through the fourth semiconductor region 24 and the second semiconductor region 22 so as to be injected into the first semiconductor region 21. Furthermore, the injection of electrons starts from the first electrode 11, and the electrons pass through the fifth semiconductor region 25 so as to be injected into the first semiconductor region 21.

At the end of the freewheeling operation (during the reverse recovery of the diode), the electrons stored in the first semiconductor region 21 during the on-state are discharged to the first electrode 11, and the holes are discharged to the second electrode 12. While current flows through the semiconductor device 100, carriers (electrons and holes) are stored in the first semiconductor region 21. The first semiconductor region 21 may need to have, for example, at least a predetermined thickness in the Z direction in order to maintain the breakdown voltage of the semiconductor device 100. The reverse recovery operation of the diode is completed when the carriers stored in the first semiconductor region 21 are discharged or disappear due to recombination. At this time, if a large amount of carriers is stored in the first semiconductor region 21, which is provided to be relatively thick, there is a risk of an increase in loss due to carrier discharge. However, in the semiconductor device 100 according to the present embodiment, the defect region LD provided in the first semiconductor region 21 in the diode region Rd prevents carriers from being stored in the first semiconductor region 21. The recombination of holes and electrons is promoted in the defect region LD provided in the first semiconductor region 21 in the diode region Rd. That is, the defect region LD in the diode region Rd reduces carrier storage in the first semiconductor region 21, and reduces the amount of carriers to be discharged via the electrode.

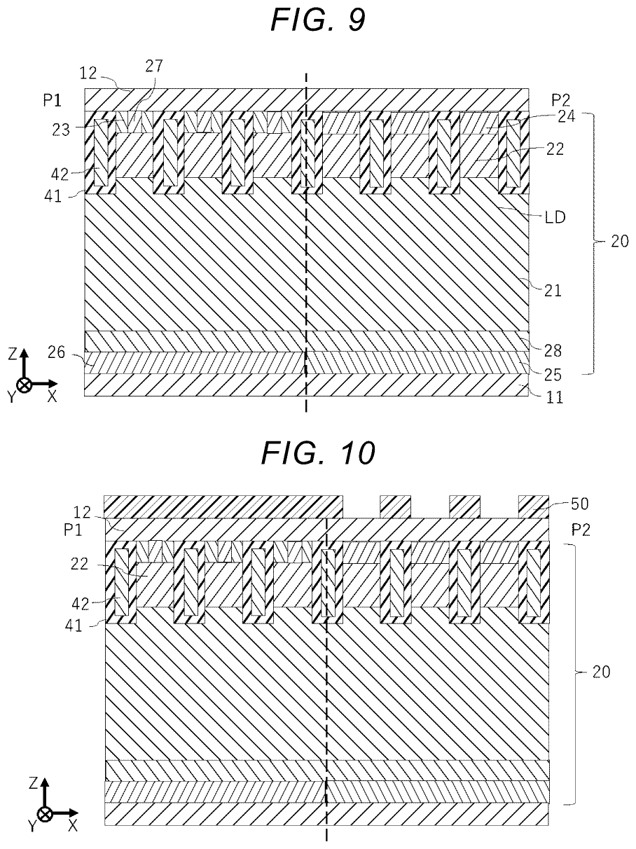

Next, a description will be given as to an example of a manufacturing method of the semiconductor device 100 according to the an embodiment with reference to FIGS. 9 to 13.

In FIG. 9, the semiconductor substrate 20, the gate insulating portion 41, the gate electrode 42, and the first electrode 11 have been formed. The semiconductor substrate 20 has the first semiconductor region 21, the second semiconductor region 22, the third semiconductor region 23, the fourth semiconductor region 24, the fifth semiconductor region 25, the sixth semiconductor region 26, the seventh semiconductor region 27, and the eighth semiconductor region 28. Steps of preparing the semiconductor substrate 20, the gate insulating portion 41, the gate electrode 42, and the first electrode 11 are not significantly different from normal manufacturing steps, and thus additional descriptions of the steps will be omitted.

The second electrode 12 is formed on the semiconductor substrate 20 by, for example, sputtering. The upper surface of the second electrode 12 is flat in FIG. 9.

Next, in the step illustrated in FIG. 10, a resist 50 is formed on the second electrode 12. The resist 50 is formed by, for example, photolithography. The resist 50 has an opening at a location that overlaps, in the Z direction, the second semiconductor region 22 located between the gate insulating portions 41 at least in the diode region Rd.

A part of the second electrode 12 is removed where the resist 50 is open (not present). The second electrode 12 is removed (etched) in the negative direction of the Z direction by etching, such as chemical dry etching (CDE).

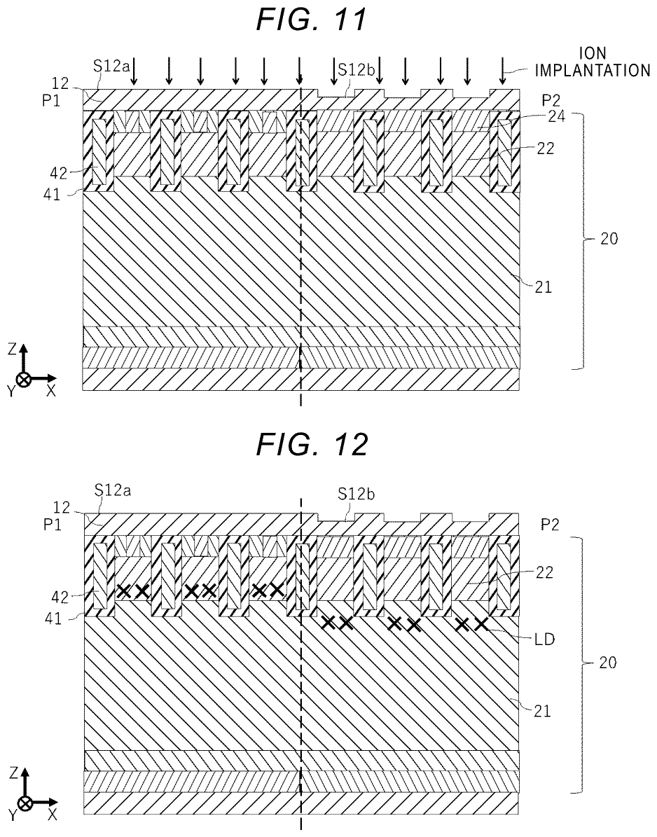

Subsequently, in the step illustrated in FIG. 11, impurity ions are implanted from the first upper surface S12a and the second upper surface S12b of the second electrode 12, the upper surface of which has been selectively removed. The implanted impurity ions penetrate the second electrode 12 in the negative Z direction and reach into the semiconductor substrate 20. Since the second electrode 12 is thin below the second upper surface S12b, the impurity ions passing through the second upper surface S12b will tend to reach deeper into the semiconductor substrate 20 in the Z direction. The injected impurities cause defects in the crystal lattice of the semiconductor substrate 20 which is, for example, monocrystalline silicon.

FIG. 12 illustrates an example of the defect region LD formed by the impurity implantation step in FIG. 11. The defect region LD below the second upper surface S12b is located further in the negative Z direction than the defect region LD below the first upper surface S12a.

In the step of selectively removing the second electrode 12, since the thickness of the second electrode 12 is controlled, the defect region LD below the first upper surface S12a can be located in the second semiconductor region 22, and the defect region LD below the second upper surface S12b can be located in the first semiconductor region 21. The deeper the second electrode 12 is etched in a region overlapping the opening of the resist 50 in FIG. 10, the thinner the second electrode 12 becomes in this region. As a result, since impurity ions pass through the thinner second electrode 12 more easily, the impurity ions can reach deeper inside the semiconductor substrate 20.

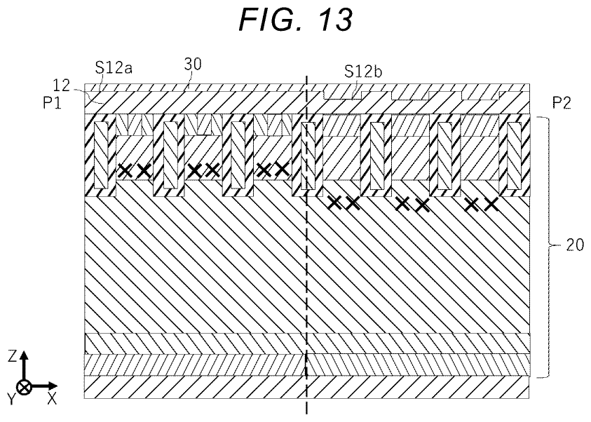

Finally, in the step illustrated in FIG. 13, the conductive layer 30 is formed on the second electrode 12. The conductive layer 30 is in contact with the first upper surface S12a and the second upper surface S12b. The conductive layer 30 is formed, for example, by a plating processing, so as to fill the unevenness of the upper surface of the second electrode 12. Here, the plating processing is, for example, an electroless plating using a plating solution. In the example of the conductive layer 30 comprising Ni and Au, a film of Ni may be formed by electroless plating using a plating solution containing Ni, and then a film of Au may be formed by electroless plating using a plating solution containing Au.

According to the semiconductor device 100 of the present embodiment, the defect region LD provided in the first semiconductor region 21 of the diode region Rd promotes the recombination of electrons and holes, thereby making it possible to reduce the reverse recovery loss of the diode. Furthermore, since the second electrode 12 has the first upper surface S12a and the second upper surface S12b having different depths in the Z direction, the step of selectively forming the defect region LD in a portion of the first semiconductor region 21, which is located in the diode region Rd, becomes more efficient, thereby making it possible to reduce manufacturing costs.

For comparison, in order to selectively form defects only in the diode, a thick mask (a mask that is thick enough to completely block ions) would be separately required to block from being implanted into the IGBT region, which reduces manufacturing efficiency and increases manufacturing costs. However, in a case where defects are also formed in the drift region of the IGBT, the carrier lifetime in the drift region will be reduced, which may cause an undesirable increase in the on-resistance of the IGBT.

According to the semiconductor device 100 of the present embodiment, impurity ions are also implanted into the second semiconductor region 22 in the transistor region Rt, but it is not necessary to form a separate thick mask in the transistor region Rt. By adjusting the thickness in the Z direction of the second electrode 12 in the transistor region Rt and the acceleration voltage for implantation of impurity ions, the impurity ions can be stopped in the second semiconductor region 22 in consideration of the shielding effect provided by the second electrode 12. Since the thickness of the second electrode 12 in the Z direction and the acceleration voltage for implantation of impurity ions can be adjusted as appropriate, the steps of forming and removing a thick mask can be omitted such that manufacturing efficiency can be improved. For comparison, when it is desired to prevent ions from being implanted into the transistor region Rt, it may be necessary to form a sufficiently thick mask separately to completely block the ions.

In addition, since crystal defects are formed in the second semiconductor region 22 that has a channel formed therein when the IGBT is turned on, it is possible to more effectively prevent an increase in the on-resistance of the IGBT as compared with a case in which crystal defects are formed in the first semiconductor region 21.

When the IGBT is turned on, a channel is formed in the second semiconductor region 22 including the defect region LD, thereby allowing current to flow through the channel. In addition, during the reverse recovery of the diode, the defect region LD provided in the first semiconductor region 21 promotes recombination of electrons and holes stored during the electrically connected state of the diode. According to the semiconductor device 100 of the present embodiment, since the reverse recovery time of the diode is shortened, the reverse recovery loss can be reduced.

According to the semiconductor device 100 of the present embodiment, the location of the defect region LD in the Z direction differs between the transistor region Rt and the diode region Rd due to the unevenness of the upper surface of the second electrode 12 (varied thickness). Therefore, since the interface between the first semiconductor region 21 and the second semiconductor region 22 has, for example, a planar shape, the second semiconductor region 22 can be formed efficiently. Specifically, the implantation of the second conductivity type impurity ions for formation of the second semiconductor region 22 can be performed through the same step in the transistor region Rt and the diode region Rd.

According to the semiconductor device 100 of the present embodiment, since the second electrode 12 is provided with the first upper surface S12a and the second upper surface S12b, formation of the defect region LD as illustrated in FIG. 2 can be easily performed. For example, when the acceleration voltage of the impurity ions to be implanted is fixed, an uneven shape of the upper surface of the second electrode 12 corresponds to a distribution in depths at which the defect region LD is formed inside the semiconductor substrate 20. Since the shape of the second electrode 12 can be controlled, it is possible to obtain a desired distribution of the defect region LD (also including a case in which the distribution is different in the transistor region Rt and the diode region Rd).

It is possible to appropriately select a locational relationship in the Z direction between the interface between the first semiconductor region 21 and the second semiconductor region 22 in the transistor region Rt and the defect region LD in the transistor region Rt. In addition, it is possible to appropriately select a locational relationship in the Z direction between the interface between the first semiconductor region 21 and the second semiconductor region 22 in the diode region Rd and the defect region LD in the transistor region Rt. For example, the interface between the first semiconductor region 21 and the second semiconductor region 22 in the diode region Rd is located closer to the first electrode 11 in the Z direction than the defect region LD in the transistor region Rt. Therefore, the anode region of the diode (the second semiconductor region 22) can be formed to be thick. Punch-through of a depletion layer in the diode region Rd can be prevented, and leakage current can be reduced.

Furthermore, since the anode region (the second semiconductor region 22) of the diode is formed to be thick, it is possible to reduce the protruding length of the gate insulating portion 41 from the interface of the first semiconductor region 21 and the second semiconductor region 22 in the direction toward the first electrode 11 in the diode region Rd. For comparison, consideration is given as to a case in which the anode region of the diode is formed to be thinner than the base region of the IGBT. The gate insulating portion 41 is provided to the same depth in the semiconductor substrate 20 across the transistor region Rt and the diode region Rd. In such a case, the protruding length of the gate insulating portion 41 from the anode region toward the first semiconductor region 21 is greater than the protruding length of the gate insulating portion 41 from the base region of the IGBT toward the first semiconductor region 21. When the anode region is made thinner than the base region of the IGBT, the protruding length of the gate insulating portion 41 in the diode region Rd increases. However, in the semiconductor device 100 according to the present embodiment, the protruding length of the gate insulating portion 41 in the diode region Rd is approximately the same as the protruding length of the gate insulating portion 41 in the transistor region Rt. Accordingly, it is possible to prevent concentration of the electric field at an end portion (a bottom portion) of the gate insulating portion 41 and to improve breakdown resistance.

Furthermore, since the protruding length of the gate insulating portion 41 is reduced, an area in which the gate insulating portion 41 covering the gate electrode 42 and the first electrode 11 face each other with the first semiconductor region 21 interposed therebetween can be reduced and as such, capacitance between the gate electrode 42 and the first electrode 11 can be reduced. It is known that gate-collector capacitance in a trench gate structure is proportional to the area of the trench protruding into a drift region. Furthermore, a surge voltage at the time of turning off the IGBT increases as gate-collector capacitance of the IGBT increases. According to the present embodiment, through reduction in the capacitance, the surge voltage at the time of turning-off can be reduced so as to reduce the loss.

Furthermore, according to the present embodiment, since it is possible to reduce the length in the Z direction of the first semiconductor region 21 in the diode region Rd, the resistance of the first semiconductor region 21 in the diode region Rd can be reduced, and conduction losses in the first semiconductor region 21 can be reduced. For comparison, consideration is given as to an example in which the defect region LD (which is formed in this comparative example at the same location in the Z direction as that of the defect region LD in the transistor region Rt) is located in the first semiconductor region 21 by forming the thin second semiconductor region 22 in the diode region Rd in the Z direction. In this comparative example, the length in the Z direction of the first semiconductor region 21 in the diode region Rd becomes greater than the length in the Z direction of the first semiconductor region 21 in the transistor region Rt.

However, according to the present embodiment, the length in the Z direction of the first semiconductor region 21 in the diode region Rd does not need to be larger than the length in the Z direction of the first semiconductor region 21 in the transistor region Rt. Therefore, it is possible to reduce the length in the Z direction of the first semiconductor region 21 in the diode region Rd. According to the present embodiment, it is thus possible to reduce the resistance of the first semiconductor region 21 in the diode region Rd and to reduce the conduction loss in the first semiconductor region 21.

In addition, since the conductive layer 30 is provided on the second electrode 12, the unevenness of the upper surface of the second electrode 12 can be filled with the conductive layer 30 such that surface flatness is ultimately achieved. For example, a plate-shaped metal member, wire, ribbon, and the like may need to be connected to the second electrode 12 (or the conductive layer 30). In this case, a flat upper surface is preferable for reliable electrical connection. In addition, the conductive layer 30 preferably contacts the second upper surface S12b. It is desirable to form a smaller amount of voids or the like between the conductive layer 30 that fills the recess portion 12c and the second electrode 12. Through the conductive layer 30 that fills the recess portion 12c, electrical resistance between the second electrode 12 and the conductive layer 30 can be kept low.

In addition, preferably, the recess portion 12c is not provided at a location of a portion overlapping the gate insulating portion 41 in the Z direction. When impurity ions are implanted, the thick second electrode 12 is provided on the gate insulating portion 41, thereby making it possible to prevent the impurity ions from reaching the gate insulating portion 41. If impurity ions reach the gate insulating portion 41, the insulating properties of the gate insulating portion 41 may deteriorate, resulting in deterioration in the breakdown resistance. According to the first embodiment, the breakdown resistance can be improved by preventing the implantation of impurity ions into the gate insulating portion 41.

### Second Embodiment

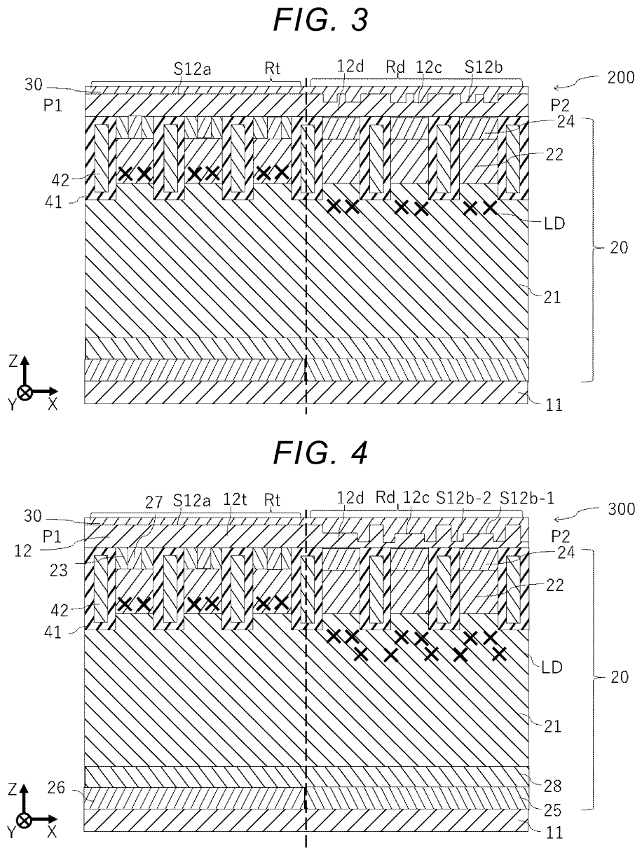

FIG. 3 is a cross-sectional view of a semiconductor device 200 according to a second embodiment. Description of aspects common to the semiconductor device 100 will be omitted to focus on differences.

In the semiconductor device 200 according to the second embodiment, the shape of the upper surface of the anode electrode 12d in the diode region Rd is different from that in the semiconductor device 100 according to the first embodiment. In the second embodiment, a plurality of recess portions 12c are provided above the second semiconductor region 22 located between a pair of gate insulating portions 41. The conductive layer 30 fills each of these recess portions 12c.

In the semiconductor device 200, reliability can be further improved by further improving the flatness of the upper surface of the conductive layer 30. In the second embodiment, a length of the recess portion 12c in the X direction (hereinafter simply referred to as a width of the recess portion 12c) is, for example, less than that in the semiconductor device 100.

When the width of the recess portion 12c becomes too large, the upper surface of the conductive layer 30 may have indentations. That is, it may be difficult to provide the complete flatness at the upper surface of the conductive layer 30. On the other hand, when the width of the recess portion 12c is too small, the conductive layer 30 may not be sufficiently embedded therein, and electrical resistance between the second electrode 12 and the conductive layer 30 may increase.

In the second embodiment, even if the pitch (a distance between the adjacent gate electrodes 42) at which the gate electrodes 42 are provided varies, a width of the recess portion 12c that allows the conductive layer 30 to be formed satisfactorily can be selected.

### Third Embodiment

FIG. 4 is a cross-sectional view of a semiconductor device 300 according to a third embodiment. Description of aspects common to the semiconductor device 100 will be omitted.

In the third embodiment, the second upper surface S12b, which is the bottom surface of the recess portion 12c provided in the anode electrode 12d, includes a plurality of surfaces (a first surface S12b-1 and a second surface S12b-2) having different locations in the Z direction. The first surface S12b-1 is located above the second semiconductor region 22 located between the pair of gate insulating portions 41. The second surface S12b-2 at least partially overlaps the gate insulating portion 41 in the Z direction.

The first surface S12b-1 is formed farther away from the semiconductor substrate 20 than the second surface S12b-2. For example, the first surface S12b-1 and the second surface S12b-2 are formed by forming resist 50 on the second electrode 12 and then performing photolithography. Here, the formation is completed through two separate steps.

The defect region LD located below the first surface S12b-1 is located farther away from the first electrode 11 than the defect region LD located below the second surface S12b-2. The second electrode 12 below the second surface S12b-2 is formed to be thin, thereby allowing implanted ions to reach a deeper location in the semiconductor substrate 20.

According to the semiconductor device 300 of the third embodiment, the defect region LD provided in the first semiconductor region 21 of the diode region Rd promotes recombination of electrons and holes. Accordingly, the reverse recovery loss of the diode can be reduced. Additionally, the defect region LD is formed in the first semiconductor region 21 even in the portion that at least partially overlaps the gate insulating portion 41 in the Z direction, thereby further promoting the recombination of electrons and holes during the reverse recovery.

In the third embodiment, at least some of the ions implanted from the second surface S12b-2 toward the semiconductor substrate 20 pass through the gate insulating portion 41 and reach the first semiconductor region 21. Since the second electrode 12 is sufficiently formed to be thin below the second surface S12b-2 so as to reduce the ions that stop in the gate insulating portion 41, insulating performance of the gate insulating portion 41 can be maintained.

### Fourth Embodiment

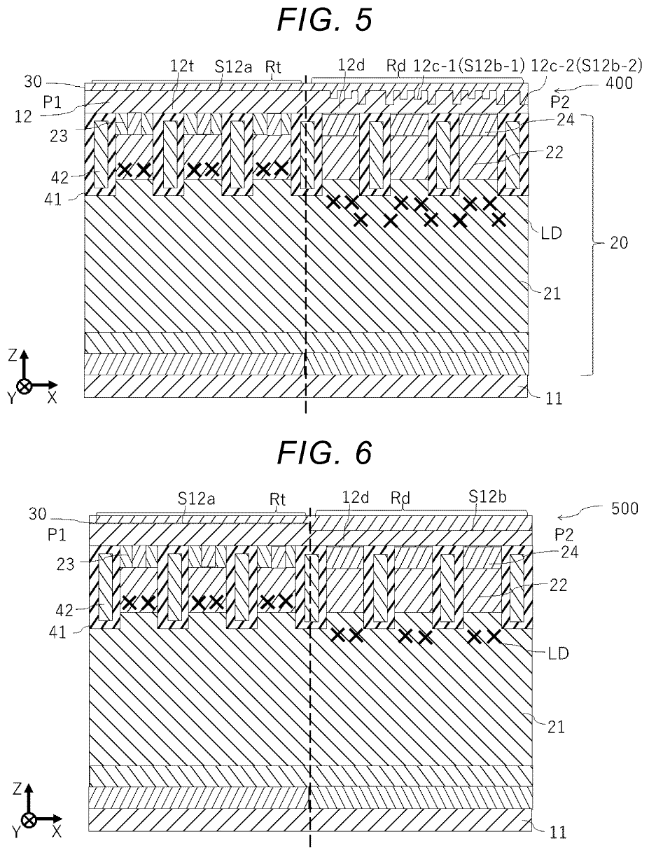

FIG. 5 is a cross-sectional view of a semiconductor device 400 according to a fourth embodiment. Description of aspects common to the semiconductor device 300 will be omitted.

In the fourth embodiment, the anode electrode 12d has a first recess portion 12c-1 and a second recess portion 12c-2 having different depths. In the fourth embodiment, the bottom surface of the first recess portion 12c-1 is referred to as the first surface S12b-1. The bottom surface of the second recess portion 12c-2 is referred to as the second surface S12b-2.

The first surface S12b-1 is located above the second semiconductor region 22 located between the pair of gate insulating portions 41. At least a part of the second surface S12b-2 overlaps the gate insulating portion 41 in the Z direction. One or more first recess portions 12c-1, each having the first surface S12b-1 as the bottom surface thereof, are provided above the second semiconductor region 22 located between the pair of gate insulating portions 41.

The first surface S12b-1 is formed to be farther away from the semiconductor substrate 20 than the second surface S12b-2. For example, the first recess portion 12c-1 (the first surface S12b-1) and the second recess portion 12c-2 (the second surface S12b-2) are formed by forming a resist 50 on the second electrode 12 and then performing photolithography. Here, the formation is completed through two separate steps.

The defect region LD located below the first surface S12b-1 is located farther away from the first electrode 11 than the defect region LD located below the second surface S12b-2. The second electrode 12 below the second surface S12b-2 is formed to be thin, thereby enabling the implanted ions to reach a deeper location in the semiconductor substrate 20.

In the semiconductor device 400 according to the fourth embodiment, since the defect region LD provided in the first semiconductor region 21 of the diode region Rd promotes the recombination of electrons and holes, the reverse recovery loss of the diode can be reduced. Additionally, since the defect region LD is formed in the first semiconductor region 21 even in a portion that at least partially overlaps the gate insulating portion 41 in the Z direction, the recombination of electrons and holes during reverse recovery is further promoted.

In the fourth embodiment, at least some of the ions implanted from the second surface S12b-2 toward the semiconductor substrate 20 pass through the gate insulating portion 41 and reach the first semiconductor region 21. Since the second electrode 12 is sufficiently formed to be thin below the second surface S12b-2 so as to reduce the ions that stop in the gate insulating portion 41, insulating performance of the gate insulating portion 41 can be maintained.

Furthermore, since the number of first recess portions 12c-1 located above the second semiconductor region 22 located between a pair of gate insulating portions 41 may be adjusted, the width of the first recess portion 12c-1 in the X direction can be appropriately optimized. The width of the first recess portion 12c-1 in the X direction can be selected so that the conductive layer 30 has good embeddability and the flatness of the upper surface of the conductive layer 30 may be improved.

Since the second recess portion 12c-2 is formed as a recess portion distinct from the first recess portion 12c-1, the width of the second recess portion 12c-2 in the X direction can be appropriately optimized. The width of the second recess portion 12c-2 in the X direction can be selected so that the conductive layer 30 has good embeddability and the flatness of the upper surface of the conductive layer 30 may be improved.

### Fifth Embodiment

FIG. 6 is a cross-sectional view of a semiconductor device 500 according to a fifth embodiment. Description of aspects common to the semiconductor device 100 will be omitted.

In the semiconductor device 500 according to the fifth embodiment, the upper surface of the anode electrode 12d in the diode region Rd is formed as the second upper surface S12b that is closer to the semiconductor substrate 20 than the first upper surface S12a. The second upper surface S12b is provided over a location that overlaps the second semiconductor region 22 in the Z direction and a location that overlap the gate insulating portion 41 in the Z direction.

In the semiconductor device 500, in the step for partially removing the second electrode 12 to form the second upper surface S12b, a resist 50 is selectively formed in the transistor region Rt. Therefore, in the process of forming the second upper surface S12b, a photomask for forming the fourth semiconductor region (the anode region) 24 in the diode region Rd may be used. Therefore, the process of forming the second upper surface S12b can be simplified to reduce manufacturing costs.

### Sixth Embodiment

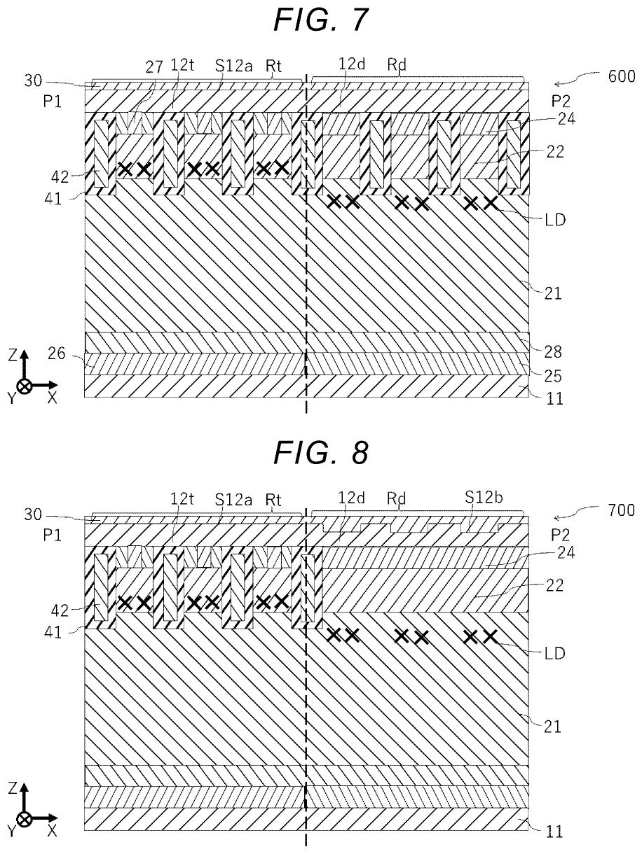

FIG. 7 is a cross-sectional view of a semiconductor device 600 according to a sixth embodiment. Description of aspects common to the semiconductor device 100 will be omitted.

In the semiconductor device 600 the upper surface of the anode electrode 12d in the diode region Rd is the first upper surface S12a that is formed to be flat from the transistor region Rt. That is, the upper surface of the anode electrode 12d does not have the recess portion 12c or the second upper surface S12b.

The shape of the second electrode 12 illustrated in FIG. 7 is formed by, for example, further adding a step of polishing the second electrode 12 to reduce the unevenness of the upper surface of the second electrode 12 (or flattening the upper surface of the second electrode 12) as compared to FIG. 12 illustrating the manufacturing method of the semiconductor device 100 according to the first embodiment. That is, although there is no unevenness on the upper surface of the second electrode 12 in FIG. 5, unevenness is present on the upper surface of the second electrode 12 in the step of implanting impurity ions for formation of the defect region LD, and the defect region LD is formed as in the first embodiment. The planarization of the second electrode 12 is performed, for example, by chemical mechanical polishing (CMP).

It is noted that it is not necessary for unevenness to be provided on the upper surface of the second electrode 12 in the step of implanting impurity ions. For example, it is possible to select a method of selectively forming a thin resist in the transistor region Rt and reducing the implantation depth of impurity ions in the transistor region Rt.

The conductive layer 30 is formed on the first upper surface S12a of the second electrode 12. The upper surface of the conductive layer 30 is flat.

In the semiconductor device 600 according to the sixth embodiment, since the upper surface of the second electrode 12 is formed to be flat, connection of metal members, wires, ribbons, and the like to the second electrode 12 can be reliably performed. In addition, the flatness of the upper surface of the conductive layer 30 provided on the second electrode 12 can be further improved.

### Seventh Embodiment

FIG. 8 is a plan view of a semiconductor device 700 according to a seventh embodiment. Description of aspects common to the semiconductor device 100 will be omitted.

In the semiconductor device 700 according to the seventh embodiment, the gate insulating portion 41 and the gate electrode 42 are not provided in the diode region Rd.

In FIG. 8, the uneven shape of the upper surface of the second electrode 12 is illustrated in the same manner as in the semiconductor device 100 according to the first embodiment, and the second upper surface S12b may be provided over the entire diode region Rd as in the semiconductor device 500 illustrated in FIG. 6. Even when the second upper surface S12b is provided over the entire diode region Rd, the gate insulating portion 41 is not present in the diode region Rd, and therefore there is no disadvantage that impurity ions will be implanted into the gate insulating portion 41 such that deterioration in the dielectric breakdown resistance would occur.

According to at least one embodiment described above, a defect region LD that is located in the second semiconductor region 22 in the transistor region Rt but is located in the first semiconductor region 21 in the diode region Rd can be formed to thereby promote the recombination of electrons and holes in the first semiconductor region 21 during reverse recovery of the diode. Losses during switching can be reduced, in particular, the reverse recovery loss of the diode can be reduced. In addition, since the second upper surface S12b that is formed to be closer to the first electrode 11 than the first upper surface S12a is provided on the upper surface of the anode electrode 12d, manufacturing costs required for implanting impurity ions can be reduced.

Hereinabove, embodiments have been described with reference to specific examples. However, the present disclosure is not limited to these specific examples. In other words, designs obtained by appropriately modifying these specific examples by a person skilled in the art are also included within the scope of the present disclosure. The various elements provided in the above-mentioned specific examples, and the arrangement, material, condition, shape, size, and the like of such elements are not limited to those described in the specific examples, and can be appropriately modified.

Furthermore, the various described embodiments can be combined with each other to the extent technically feasible, and, as such, combinations thereof are also included within the scope of the present disclosure. In addition,, various possible modifications and alterations to the example embodiments will be apparent to a person of ordinary skill in the art will, and it should be understood that these modifications and alterations also fall within the scope of the present disclosure.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor substrate having a transistor region and a diode region spaced from the transistor region;
a first electrode on a first side of the semiconductor substrate;
a second electrode on a second side of the semiconductor substrate, the second electrode having a first upper surface in the transistor region and a second upper surface in the diode region, the second upper surface being closer to the semiconductor substrate than is the first upper surface; and
a plurality of gate electrodes in the semiconductor substrate between the first and second electrodes in a first direction, each gate electrode being surrounded by a gate insulating film, wherein
the semiconductor substrate includes:
a first semiconductor region on the first electrode;
a second semiconductor region on the first semiconductor region and between adjacent pairs of gate electrodes in the plurality of gate electrodes;
a third semiconductor region in the transistor region on the second semiconductor region; and
a defect region, the defect region having a higher crystal defect density than a crystal defect density of the semiconductor substrate outside the defect region.

2. The semiconductor device according to claim 1, wherein a distance between the defect region and the second electrode in the transistor region is less than a distance between the defect region and the second electrode in the diode region.

3. The semiconductor device according to claim 1, wherein an interface between the first semiconductor region and the second semiconductor region in the diode region is located closer to the first electrode than the defect region in the transistor region.

4. The semiconductor device according to claim 1, wherein an interface between the first semiconductor region and the second semiconductor region is located at the same distance from the first electrode in both the transistor region and the diode region.

5. The semiconductor device according to claim 1, further comprising:
a conductive layer on the second electrode covering the first upper surface and the second upper surface.

6. The semiconductor device according to claim 1, wherein:
the plurality of the gate electrodes is in diode region, and the planar area of an upper surface of the second semiconductor regions between adjacent pairs of gate electrodes in the diode region is greater than the planar area of the second upper surface at a position between the respective adjacent pairs of gate electrodes in the diode region.

7. The semiconductor device according to claim 1, wherein the second electrode in the diode region includes portions protruding upward in the first direction from the second upper surface, the portions being at a position between adjacent pairs of gate electrodes.

8. The semiconductor device according to claim 1, wherein the plurality of gate electrodes is only in the transistor region.

9. A semiconductor device, comprising:
a semiconductor substrate having a transistor region and a diode region spaced from the transistor region;
a first electrode on a first side of the semiconductor substrate;
a second electrode on a second side of the semiconductor substrate; and
a plurality of gate electrodes in the semiconductor substrate between the first and second electrodes in a first direction, each gate electrode being surrounded by a gate insulating film, wherein
the semiconductor substrate includes:
a first semiconductor region on the first electrode;
a second semiconductor region on the first semiconductor region and between adjacent pairs of gate electrodes in the plurality of gate electrodes;
a third semiconductor region in the transistor region on the second semiconductor region; and
a defect region, the defect region having a higher crystal defect density than a crystal defect density of the semiconductor substrate outside the defect region, and
the defect region is in the second semiconductor region in the transistor region and the first semiconductor region in the diode region, a depth of the defect region being different in the transistor region and the diode region.

10. The semiconductor device according to claim 9, wherein the second electrode has the same minimum thickness in the transistor region and the diode region.

11. The semiconductor device according to claim 9, wherein
the second electrode has a first maximum thickness in the transistor region and a second maximum thickness in the diode region, and
the second maximum thickness is less than the first maximum thickness.

12. The semiconductor device according to claim 11, further comprising:
a conductive layer on the second electrode, wherein
an upper surface of the conductive layer is substantially flat across the transistor region and the diode region.

13. The semiconductor device according to claim 9, wherein an upper surface of the second electrode is uneven in the diode region and substantially flat in the transistor region.

14. The semiconductor device according to claim 13, further comprising:
a conductive layer on the second electrode, wherein
an upper surface of the conductive layer is substantially flat across the transistor region and the diode region.

15. The semiconductor device according to claim 9, wherein
the second electrode has a first upper surface in the transistor region and a second upper surface in the diode region, and
the second upper surface is closer to the semiconductor substrate than is the first upper surface.

16. The semiconductor device according to claim 9, wherein an interface between the first semiconductor region and the second semiconductor region is located at the same distance from the first electrode in both the transistor region and the diode region.

17. The semiconductor device according to claim 9, wherein the plurality of gate electrodes is only in the transistor region.

18. A manufacturing method for a semiconductor device, the manufacturing method comprising:
preparing a semiconductor substrate having a transistor region and a diode region, the semiconductor substrate including a first semiconductor region of a first conductivity type, a second semiconductor region of a second conductivity type, the second semiconductor region being provided on the first semiconductor region, a third semiconductor region of the first conductivity type, the third semiconductor region being provided on the second semiconductor region in the transistor region, and a plurality of gate electrodes facing the second semiconductor region with a gate insulating portion interposed therebetween;
forming an upper electrode on the semiconductor substrate;
forming a resist on the upper electrode, the resist having an opening above the second semiconductor region in the diode region;
selectively removing an upper portion of the upper electrode so as to form a first upper surface in the transistor region and a second upper surface in the diode region, the second upper surface being formed closer to the semiconductor substrate than the first upper surface; and
implanting a dopant into the semiconductor substrate through the upper electrode so as to form a defect region in the semiconductor substrate, the defect region having a higher crystal defect density than a crystal defect density of the semiconductor substrate outside the defect region.

19. The manufacturing method according to claim 18, further comprising:
forming a conductive layer on the upper electrode by plating processing.

20. The manufacturing method according to claim 18, wherein the defect region is formed in the first semiconductor region in the diode region.
